(19) United States
(12) Patent Application Publication
(10) Pub. No.: US 2025/0280725 A1
(43) Pub. Date: Sep. 4, 2025

(54) METHOD OF PRODUCING PHOTOELECTRIC CONVERSION ELEMENT AND PHOTOELECTRIC CONVERSION ELEMENT

(71) Applicant: NGK INSULATORS, LTD., Nagoya-City (JP)

(72) Inventors: Atsushi WAKAMIYA, Uji-Shi (JP); Noboru OHASHI, Uji-Shi (JP); Ryuji KANEKO, Kyoto-Shi (JP); Kenshin KITOH, Nagoya-Shi (JP); Tsutomu ITO, Konan-Shi (JP)

(73) Assignee: NGK INSULATORS, LTD., Nagoya-City (JP)

(21) Appl. No.: 19/211,443

(22) Filed: May 19, 2025

Related U.S. Application Data
(63) Continuation of application No. PCT/JP2023/039912, filed on Nov. 6, 2023.

(30) Foreign Application Priority Data
Nov. 22, 2022 (JP) 2022-186852

(51) Int. Cl. H10K 71/40; H10K 30/40

(52) U.S. Cl. CPC H10K 71/421; H10K 30/40

(57) ABSTRACT

A method of producing a photoelectric conversion element includes the steps of: preparing a laminate including a first electrode, an electron-transporting layer, a perovskite semiconductor film, a hole-transporting layer, and a second electrode; and irradiating the laminate with infrared light.

### CROSS-REFERENCE TO RELATED APPLICATIONS

This application is a continuation under 35 U.S.C. 120 of International Application PCT/JP2023/039912 having the International Filing Date of Nov. 6, 2023 and having the benefit of the earlier filing date of Japanese Application No. 2022-186852, filed on Nov. 22, 2022. Each of the identified applications is fully incorporated herein by reference.

### BACKGROUND OF THE INVENTION

### 1. Field of the Invention

The present invention relates to a method of producing a photoelectric conversion element and a photoelectric conversion element.

### 2. Description of the Related Art

In recent years, the development of a photoelectric conversion element using a perovskite semiconductor material has been attracting attention. Although the perovskite semiconductor material is an inorganic material, the application of a solution of the perovskite semiconductor material enables the production of a perovskite semiconductor film. For example, there is a proposal of a method of producing a perovskite layer, the method including: applying a solution containing a Sn-based perovskite compound to a substrate; then applying a poor solvent to the substrate; and subjecting the substrate to annealing treatment (see, for example, Patent Literature 1). When many photoelectric conversion elements each including such perovskite layer are produced, a defective product having insufficient photoelectric conversion performance may be produced, and hence the method is susceptible to improvement in terms of production yield.

### CITATION LIST

### Patent Literature

[PTL 1] WO 2019/182058 A1

### SUMMARY OF THE INVENTION

A primary object of the present invention is to provide a method of producing a photoelectric conversion element by which the production yield of a photoelectric conversion element having excellent photoelectric conversion performance can be improved.

[1] A method of producing a photoelectric conversion element according to one embodiment of the present invention includes the steps of: preparing a laminate including a first electrode, an electron-transporting layer, a perovskite semiconductor film, a hole-transporting layer, and a second electrode; and irradiating the laminate with infrared light.

[2] In the method of producing a photoelectric conversion element according to the above-mentioned item [1], the infrared light may have a wavelength peak of 3.5 μm or less.

[3] In the method of producing a photoelectric conversion element according to the above-mentioned item [1] or [2], the infrared light may have a spectral half-width of 3.0 μm or less.

[4] In the method of producing a photoelectric conversion element according to any one of the above-mentioned items [1] to [3], in the step of irradiating the laminate with the infrared light, the laminate may be irradiated with the infrared light until a content of water in the perovskite semiconductor film becomes 1,000 ppm (mass fraction) or less.

[5] In the method of producing a photoelectric conversion element according to any one of the above-mentioned items [1] to [4], in the step of irradiating the laminate with the infrared light, the laminate may have a temperature of 100° C. or less.

[6] A photoelectric conversion element according to another aspect of present invention is produced by irradiating a laminate including a first electrode, an electron-transporting layer, a perovskite semiconductor film, a hole-transporting layer, and a second electrode with infrared light until a content of water in the perovskite semiconductor film becomes 1,000 ppm (mass fraction) or less.

According to the embodiments of the present invention, the production yield of a photoelectric conversion element having excellent photoelectric conversion performance can be improved.

### BRIEF DESCRIPTION OF THE DRAWINGS

FIG. 1 is a schematic view for describing a method of producing a photoelectric conversion element according to one embodiment of the present invention.

FIG. 2 is a schematic sectional view of a photoelectric conversion element according to one embodiment of the present invention.

FIG. 3 is a schematic configuration view of an irradiation unit of FIG. 1.

FIG. 4 is a sectional view of the irradiation unit of FIG. 3 taken along the line IV-IV′.

### DESCRIPTION OF THE EMBODIMENTS

Embodiments of the present invention are described below with reference to the drawings. The present invention is not limited to those embodiments. In addition, for clearer illustration, some widths, thicknesses, shapes, and the like of respective portions may be schematically illustrated in the drawings in comparison to the embodiments. However, each of the widths, the thicknesses, the shapes, and the like is merely an example, and does not limit the understanding of the present invention.

### A. Outline of Method of Producing Photoelectric Conversion Element

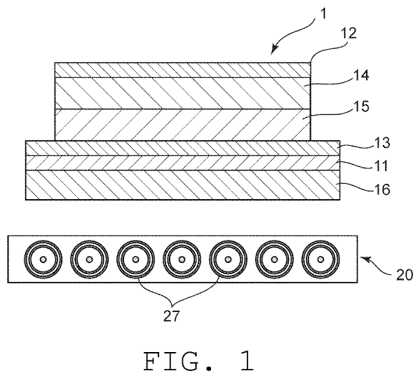

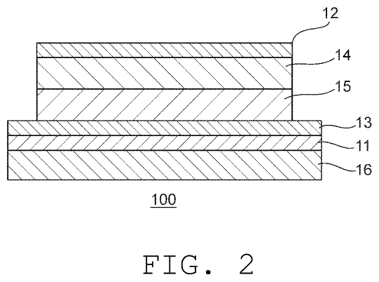

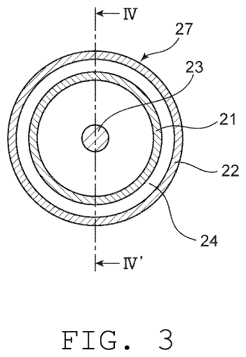

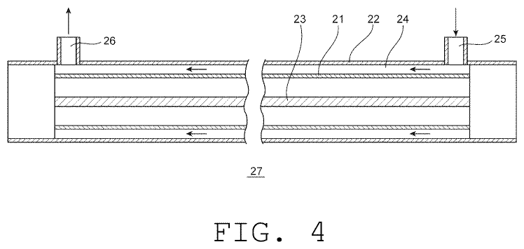

FIG. 1 is a schematic view for describing a method of producing a photoelectric conversion element according to one embodiment of the present invention. FIG. 2 is a schematic sectional view of a photoelectric conversion element according to one embodiment of the present invention. FIG. 3 is a schematic view of an irradiation unit of FIG. 1. FIG. 4 is a sectional view of the irradiation unit of FIG. 3 taken along the line IV-IV′.

The method of producing a photoelectric conversion element according to one embodiment of the present invention includes a step (preparation step) of preparing a laminate 1 and a step (infrared light irradiation step) of irradiating the laminate 1 with infrared light. The laminate 1 includes a first electrode 11, an electron-transporting layer 13, a perovskite semiconductor film 15, a hole-transporting layer 14, and a second electrode 12. According to such method, the infrared light applied to the laminate acts on the perovskite semiconductor film, the electron-transporting layer, the hole-transporting layer, and/or an interface between the perovskite semiconductor film and any other layer. Thus, even when the laminate prepared in the preparation step is a defective product having insufficient photoelectric conversion performance, the photoelectric conversion performance is restored, and hence excellent photoelectric conversion performance can be expressed over the entirety of the photoelectric conversion element. As a result, the production yield of the photoelectric conversion element can be improved.

In one embodiment, in the infrared light irradiation step, the laminate 1 is irradiated with the infrared light until the content of water in the perovskite semiconductor film 15 becomes, for example, 1,000 ppm (mass fraction) or less, preferably 500 ppm (mass fraction) or less, more preferably 300 ppm (mass fraction) or less. The content of the water in the perovskite semiconductor film may be measured with a Karl Fischer moisture meter.

In the infrared light irradiation step, when the laminate is irradiated with the infrared light until the content of the water in the perovskite semiconductor film becomes equal to or less than the above-mentioned upper limits, the water in the perovskite semiconductor film is sufficiently reduced, and hence an influence of the presence of the water on photoelectric conversion is reduced. Accordingly, a photoelectric conversion element having excellent photoelectric conversion performance can be stably produced.

The content of the water in the perovskite semiconductor film is preferably as small as possible. The lower limit of the content of the water in the perovskite semiconductor film is typically the detection limit sensitivity of the Karl Fischer moisture meter to be used, and is, for example, 0 ppm.

In the following, details about the respective steps of the method of producing a photoelectric conversion element are described.

### B. Preparation Step

### B-1. Laminate

As illustrated in FIG. 1, in the preparation step, the laminate 1 is prepared.

In one embodiment, the laminate 1 includes the first electrode 11, the electron-transporting layer 13, the perovskite semiconductor film 15, the hole-transporting layer 14, and the second electrode 12 in the stated order. The laminate 1 of the illustrated example further includes a base material 16. The base material 16 is positioned on the opposite side of the electron-transporting layer 13 with respect to the first electrode 11. The laminate 1 may further include the base material 16 on the opposite side of the hole-transporting layer 14 with respect to the second electrode 12, though such arrangement is not shown.

In the laminate 1, the arrangement of the electron-transporting layer 13 and the hole-transporting layer 14 may be reversed. In other words, the laminate 1 may include the first electrode 11, the hole-transporting layer 14, the perovskite semiconductor film 15, the electron-transporting layer 13, and the second electrode 12 in the stated order.

The laminate 1 has any appropriate shape when viewed from its lamination direction. Examples of the shape of the laminate when viewed from the lamination direction include a triangle, a quadrangle, a pentagon, a polygon that is a hexagon or more, a circular shape, and an elliptical shape.

Such laminate 1 may be produced by any appropriate method. Examples of the method of producing a laminate include: a method of producing a perovskite solar cell described in JP 2022-117248 A; a method of producing a solar cell described in WO 2019/182058 A1; and a method of producing a semiconductor described in JP 2021-145080 A. The entire descriptions of those publications are incorporated herein by reference.

In the following, details about the configuration of the laminate are described.

### B-1-1. Base Material

Any appropriate substrate that may be used in a photoelectric conversion element may be adopted as the base material 16. The base material 16 typically has flexibility. As a material for the base material 16, there are given, for example, glass, ceramics, and a resin material.

Examples of the ceramics include aluminum oxide (Al₂O₃), silicon oxide (SiO₂), silicon nitride (Si₃N₄), and silicon oxynitride (Si₄O₅N₃). The ceramics may be used alone or in combination thereof.

Examples of the resin material include: polyolefins, such as polyethylene and polypropylene; polyesters, such as polyethylene terephthalate and polyethylene naphthalate; ionomers; polyvinyl chloride; polyvinylidene chloride; polyvinyl alcohol; polycarbonate; polystyrene; polyacrylonitrile; an ethylene-vinyl acetate copolymer; an ethylene-vinyl alcohol copolymer; an ethylene-methacrylic acid copolymer; and polyamide. The resin materials may be used alone or in combination thereof.

Of the materials for the base materials 16, glass is preferred. The base material 16 may be formed from a single base material, or may be a laminate obtained by laminating two or more layers.

The shape of the base material 16 when viewed from its thickness direction is the same as the shape of the laminate 1 described above.

The thickness of the base material 16 is, for example, 1 μm or more, and is, for example, 100 mm or less, preferably 1 mm or less.

### B-1-2. First Electrode

In one embodiment, the first electrode 11 is directly arranged on the base material 16. The first electrode 11 may be arranged on the entirety of the surface of the base material 16, or may be arranged only on part of the surface of the base material 16. In the illustrated example, the first electrode 11 is arranged on the entirety of the surface of the base material 16. The first electrode 11 is typically a transparent electrode. As a material for the transparent electrode, there are given, for example, carbon, a conductive metal oxide, and a conductive polymer.

Examples of the carbon include carbon black, a carbon nanotube, and graphene.

Examples of the conductive metal oxide include tin-doped indium oxide (ITO), impurity-doped indium oxide (In₂O₃), impurity-doped zinc oxide (ZnO), and fluorine-doped tin dioxide (FTO).

Examples of the conductive polymer include poly(3,4-ethylenedioxythiophene)polystyrene sulfonate (PEDOT:PSS), polyaniline, and polyacetylene.

Those materials for transparent electrodes may be used alone or in combination thereof. Of the materials for transparent electrodes, the conductive polymer and the conductive metal oxide are preferred, and PEDOT:PSS and tin-doped indium oxide (ITO) are more preferred. The first electrode 11 may be formed from a single thin film, or may be formed by laminating two or more thin films.

The thickness of the first electrode 11 is adjusted in any appropriate manner so that a sheet resistance per unit area may be less than 15 Ωmm².

In addition, the first electrode 11 may include a metal material as long as the material has a structure that can transmit light. Examples of the structure that can transmit light include a mesh shape and a stripe shape. Examples of the metal material include gold, silver, copper, aluminum, nickel, indium, and titanium. The metal materials may be used alone or in combination thereof.

### B-1-3. Electron-Transporting Layer

The electron-transporting layer 13 increases the active surface area of the perovskite semiconductor film 15 (light-absorbing layer) to improve photoelectric conversion efficiency, and facilitates the collection of an electron by the first electrode 11. The electron-transporting layer 13 is positioned on the opposite side of the base material 16 with respect to the first electrode 11. In the illustrated example, the electron-transporting layer 13 is directly arranged on the first electrode 11. The electron-transporting layer 13 may be arranged on the entirety of the surface of the first electrode 11, or may be arranged only on part of the surface of the first electrode 11. In the illustrated example, the electron-transporting layer 13 is arranged on the entirety of the surface of the first electrode 11.

The electron-transporting layer 13 typically includes an n-type semiconductor, and preferably includes an n-type metal oxide semiconductor.

Examples of the metal oxide include titanium oxide (TiO₂) (including mesoporous TiO₂), tin oxide (SnO₂), and zinc oxide (ZnO).

The metal oxides may be used alone or in combination thereof. Of the metal oxides, tin oxide (SnO₂) is preferred. The electron-transporting layer 13 may be formed from a single layer, or may be formed by laminating two or more layers.

The thickness of the electron-transporting layer 13 is not particularly limited. The thickness is, for example, 1 nm or more, and is, for example, 300 nm or less, preferably 100 nm or less. When the thickness of the electron-transporting layer falls within the above-mentioned ranges, an electron can be efficiently collected from the perovskite semiconductor film.

In addition, the electron-transporting layer 13 may include an organic semiconductor material such as a fullerene derivative.

### B-1-4. Perovskite Semiconductor Film

The perovskite semiconductor film 15 is a light-absorbing layer (photoactive layer), and can perform photoelectric conversion by moving an electron and a hole excited by light absorption. The perovskite semiconductor film 15 is positioned on the opposite side of the first electrode 11 with respect to the electron-transporting layer 13. In the illustrated example, the perovskite semiconductor film 15 is directly arranged on the electron-transporting layer 13. The perovskite semiconductor film 15 may be arranged on the entirety of the surface of the electron-transporting layer 13, or may be arranged only on part of the surface of the electron-transporting layer 13. In the illustrated example, the perovskite semiconductor film 15 is arranged in the central portion of the surface of the electron-transporting layer 13, and the perovskite semiconductor film 15 is not formed on the end portion of the surface of the electron-transporting layer 13.

The perovskite semiconductor film 15 has a perovskite crystal structure. The perovskite semiconductor film 15 contains a perovskite crystal and/or a perovskite complex. A material for the perovskite semiconductor film 15 is typically, for example, a compound represented by the general formula (ABX₃).

A in the general formula (ABX₃) represents, for example, an organic ammonium (protonated organic amino compound) or an alkali metal cation.

Examples of the organic amino compound include: alkylamines, such as methylamine, ethylamine, n-butylamine, di-n-butylamine, di-n-hexylamine, trimethylamine, triethylamine, methyl-n-hexylamine, methyldiethylamine, tri-n-hexylamine, and tri-t-butylamine; imidazole; pyrrole; aziridine; carbazole; formamidine; guanidine; aniline; pyridine; 4-t-butylpyridine; phenethylamine; and 5-aminovaleric acid.

Preferred examples of such organic ammonium include: alkylammoniums, such as methylammonium, ethylammonium, n-butylammonium, di-n-butylammonium, di-n-hexylammonium, trimethylammonium, triethylammonium, methyl-n-hexylammonium, methyldiethylammonium, tri-n-hexylammonium, and tri-t-butylammonium; imidazolium; aziridinium; formamidinium; guanidinium; anilinium; pyridinium; 4-t-butylpyridinium; and phenethylammonium.

The alkali metal cation is a monovalent cation. Examples of the alkali metal include cesium, potassium, and rubidium.

Such As may be used alone or in combination thereof. Of such As, a combination of an organic ammonium (protonated organic amino compound) and an alkali metal cation is preferred, a combination of a protonated alkylamine (alkylammonium), a protonated formamidine (formamidinium), and an alkali metal cation is more preferred, and a combination of a protonated methylamine (methylammonium, MA⁺), a protonated formamidine (formamidinium, FA⁺), and a cesium cation (Cs⁺) is still more preferred.

When A in the general formula (ABX₃) represents a combination of an alkylammonium (methylammonium), a formamidinium, and an alkali metal cation (cesium cation), the molar ratio of the alkylammonium with respect to 1 mol of the alkali metal cation is, for example, from 1 to 5, and the molar ratio of the formamidinium with respect to 1 mol of the alkali metal cation is, for example, from 14 to 18.

B in the general formula (ABX₃) represents, for example, a divalent metal cation, and preferably represents, for example, a cation of an element belonging to Group XIV (metal element classified into Group XIV in the periodic table defined by IUPAC in 2019), such as lead or tin.

Such Bs may be used alone or in combination thereof. In addition, B may be mixed with a small amount of a trivalent cation, such as an indium or antimony ion, in addition to the above-mentioned divalent metal cation. Of those Bs, a cation of an element belonging to Group XIV is preferred, and a cation of lead (Pb) is more preferred.

X in the general formula (ABX₃) represents, for example, an ion of a halogen atom (halide) or an anion source, and preferably represents, for example, a halogen atom. Specific examples of the halogen atom include chlorine, bromine, and iodine. That is, examples of the halide include a chloride ion, a bromide ion, and an iodide ion.

Such Xs may be used alone or in combination thereof. Of those Xs, an ion of a halogen atom is preferred, and a combination of a bromide ion (Br⁻) and an iodide ion (I⁻) is more preferred.

The compound represented by the general formula (ABX₃) is particularly preferably a perovskite compound having the composition of Cs_{0.05}FA_{0.80}MA_{0.15}PdI_{2.68}Br_{0.32} or a perovskite compound having the composition of Cs_{0.05}FA_{0.80}MA_{0.15}PdI_{2.75}Br_{0.25}.

The thickness of the perovskite semiconductor film 15 is, for example, 50 nm or more, preferably 200 nm or more, and is, for example, 1,000 nm or less, preferably 800 nm or less. When the thickness of the perovskite semiconductor film falls within the above-mentioned ranges, light absorption efficiency, and electron and hole diffusion lengths can be secured in a balanced manner, and the efficiency with which light reflected by an electrode is absorbed can be improved. The thickness of the perovskite semiconductor film may be typically measured with a cross-sectional scanning electron microscope (cross-sectional SEM).

In a range measuring 500 nm by 500 nm in a horizontal direction when the surface of the perovskite semiconductor film 15 is subjected to measurement with a scanning electron microscope, the height difference of the surface is preferably 50 nm or less (from −25 nm to +25 nm), more preferably 40 nm or less (from −20 nm to +20 nm). When the height difference of the surface of the perovskite semiconductor film is equal to or less than the above-mentioned upper limits, a balance between the light absorption efficiency and an exciton diffusion length can be easily secured, and the efficiency with which the light reflected by the electrode is absorbed can be further improved.

### B-1-5. Hole-Transporting Layer

The hole-transporting layer 14 has a function of transporting charge. The hole-transporting layer 14 is positioned on the opposite side of the electron-transporting layer 13 with respect to the perovskite semiconductor film 15. In the illustrated example, the hole-transporting layer 14 is directly arranged on the perovskite semiconductor film 15. The hole-transporting layer 14 may be arranged on the entirety of the surface of the perovskite semiconductor film 15, or may be arranged only on part of the surface of the perovskite semiconductor film 15. In the illustrated example, the hole-transporting layer 14 is arranged on the entirety of the surface of the perovskite semiconductor film 15.

Any appropriate hole-transporting material that can receive a hole from the perovskite semiconductor film and transport the hole may be adopted as a material for the hole-transporting layer 14. Examples of the hole-transporting material include a conductor, a semiconductor, and an organic hole-transporting material.

Examples of the conductor and the semiconductor include: compound semiconductors each containing monovalent copper, such as CuI, CuSCN, CuInSe₂, and CuS; and compounds each containing a metal except copper, such as GaP, NiO, CoO, FeO, Bi₂O₃, MoO₂, and Cr₂O₃.

Examples of the organic hole-transporting material include: polythiophene derivatives, such as poly-3-hexylthiophene (P3HT) and polyethylenedioxythiophene (PEDOT); fluorene derivatives such as 2,2′,7,7′-tetrakis-(N,N-di-p -methoxyphenylamine)-9,9′-spirobifluorene (Spiro-OMeTAD); carbazole derivatives such as polyvinylcarbazole; triphenylamine derivatives such as poly[bis(4-phenyl) (2,4,6-trimethylphenyl)amine] (PTAA); diphenylamine derivatives; polysilane derivatives; and polyaniline derivatives.

The hole-transporting materials may be used alone or in combination thereof. Of the hole-transporting materials, a triphenylamine derivative and a fluorene derivative are preferred, a fluorene derivative is more preferred, Spiro-OMeTAD is still more preferred. When the hole-transporting material is such material, the hole mobility of the hole-transporting layer can be improved. The hole-transporting layer 14 may be formed from a single layer, or may be formed by laminating two or more layers.

The hole-transporting layer 14 preferably further contains an oxidizing agent. When the hole-transporting layer contains the oxidizing agent, its hole-transporting characteristic can be further improved.

Examples of the oxidizing agent include lithium bis(trifluoromethylsulfonyl)imide (LiTFSI), silver bis(trifluoromethylsulfonyl)imide, trifluoromethylsulfonyloxy silver, NOSbF6, SbCl5, SbF5, tris(2-(1H-pyrazol-1-yl)-4tert-butylpyridine)cobalt(III) tri[bis(trifluoromethane)sulfonimide], and 4-isopropyl-4′-methyldiphenyliodonium tetrakis (pentafluorophenyl) borate.

The oxidizing agents may be used alone or in combination thereof. Of the oxidizing agents, lithium bis(trifluoromethylsulfonyl)imide (LiTFSI) and tris(2-(1H-pyrazol-1-yl)-4-tert-butylpyridine)cobalt(III) tri[bis(trifluoromethane)sulfonimide] are preferred. Any appropriate value may be adopted as the content of the oxidizing agent in the hole-transporting layer.

In addition, the hole-transporting layer 14 may further contain a basic compound. Examples of the basic compound include t-butylpyridine (TBP), 2-picoline, and 2,6-lutidine. The basic compounds may be used alone or in combination thereof. Of the basic compounds, t-butylpyridine is preferred. Any appropriate value may be adopted as the content of the basic compound in the hole-transporting layer.

The thickness of the hole-transporting layer 14 is, for example, 1 nm or more, preferably 10 nm or more, and is, for example, 1,000 nm or less, preferably 200 nm or less. When the thickness of the hole-transporting layer falls within the above-mentioned ranges, the hole mobility thereof can be further improved.

### B-1-6. Second Electrode

The first electrode 11 and the second electrode 12 each have a function of taking charge out of the perovskite semiconductor film 15. In one embodiment, at least part of the second electrode 12 is positioned on the opposite side of the perovskite semiconductor film 15 with respect to the hole-transporting layer 14, and is directly arranged on the hole-transporting layer 14. In the illustrated example, the second electrode 12 is arranged on the entirety of the surface of the hole-transporting layer 14.

The second electrode 12 may be a metal electrode that does not transmit light, or may be a transparent electrode to be described in the same manner as in the first electrode 11. The second electrode 12 may be formed from a single thin film, or may be formed by laminating two or more thin films.

In one embodiment, the second electrode 12 is a metal electrode that does not transmit light. A metal material for the metal electrode is, for example, gold, silver, copper, aluminum, nickel, indium, or titanium, and is preferably, for example, gold. The metal materials may be used alone or in combination thereof.

The thickness of the second electrode 12 is adjusted in any appropriate manner so that a sheet resistance per unit area may be less than 15 Ω/mm².

### C. Infrared Light Irradiation Step

In the infrared light irradiation step, the above-mentioned laminate 1 is irradiated with infrared light through use of any appropriate infrared light irradiation apparatus 20. The infrared light irradiation apparatus 20 typically irradiates the entirety of the laminate 1 with the infrared light in a uniform manner. An infrared light irradiation direction is not particularly limited as long as the entirety of the laminate can be irradiated with the infrared light. The laminate 1 may be irradiated with the infrared light from one side (the second electrode side or the first electrode (base material) side) in its lamination direction, or may be irradiated with the infrared light from a direction intersecting the lamination direction. In the illustrated example, the infrared light irradiation apparatus 20 is arranged while keeping a predetermined interval from the laminate 1 in the lamination direction, and the apparatus irradiates the laminate 1 with the infrared light from the first electrode side.

The wavelength peak of the infrared light is, for example, 5.0 μm or less, preferably 3.5 μm or less, more preferably 2.5 μm or less, and is, for example, 0.8 μm or more, preferably 1.0 μm or more. When the wavelength peak of the infrared light is positioned in the above-mentioned ranges, energy can be sufficiently applied to the water in the perovskite semiconductor film, and hence the water can be smoothly reduced. Accordingly, the content of the water in the perovskite semiconductor film can be smoothly adjusted to be equal to or less than the above-mentioned upper limits. In particular, the water has an absorption wavelength of 2.74 μm corresponding to symmetric stretching vibration, and an absorption wavelength of 2.66 μm corresponding to asymmetric stretching vibration. Accordingly, when the wavelength peak of the infrared light is 3.5 μm or less, the energy can be efficiently applied to the water in the perovskite semiconductor film.

The spectral half-width of the infrared light is, for example, 4.0 μm or less, preferably 3.0 μm or less, more preferably 2.5 μm or less. When the spectral half-width of the infrared light is equal to or less than the above-mentioned upper limits, the configuration of the laminate can be suppressed from being heated through the reception of energy while the energy can be applied to the water in the perovskite semiconductor film.

When the laminate is heated, the electron-transporting layer, the perovskite semiconductor film, and/or the hole-transporting layer described above may deteriorate owing to the heat. In this respect, in the embodiment of the present invention, the temperature of the laminate can be suppressed from excessively increasing in the infrared light irradiation step because the spectral half-width of the infrared light is equal to or less than the above-mentioned upper limits.

More specifically, in the infrared light irradiation step, the temperature of the laminate is maintained at, for example, 100° C. or less, preferably 80° C. or less, more preferably 60° C. or less. Accordingly, the deterioration of a photoelectric conversion element to be produced can be suppressed, and hence a photoelectric conversion element having excellent photoelectric conversion performance can be stably produced. The lower limit of the temperature of the laminate in the infrared light irradiation step is typically 30° C.

The irradiation energy of the infrared light per unit area is, for example, 0.10 W/cm² or more, preferably 0.15 W/cm² or more, and is, for example, 2.0 W/cm² or less. The irradiation time of the infrared light may be adjusted in any appropriate manner in accordance with the irradiation energy. The irradiation time of the infrared light is, for example, 1 minute or more, preferably 5 minutes or more, and is, for example, 60 minutes or less, preferably 20 minutes or less.

The infrared light irradiation apparatus 20 that can emit the above-mentioned infrared light is, for example, a wavelength control heater (infrared heater) described in JP 2012-132662 A. The entire description of the publication is incorporated herein by reference.

More specifically, as illustrated in FIG. 1, a wavelength control heater 20 includes a plurality of irradiation units 27. The plurality of irradiation units 27 each extend in a predetermined direction (paper thickness direction in FIG. 1). The plurality of irradiation units 27 are arranged in parallel in a direction perpendicular to a lengthwise direction while being spaced from each other.

As illustrated in each of FIG. 3 and FIG. 4, the irradiation units 27 each include a filament 23, a first tube 21, and a second tube 22.

The application of a voltage enables the filament 23 to apply infrared light. In the illustrated example, the filament 23 is arranged at the center of the internal space of the first tube 21.

The first tube 21 is arranged in the internal space of the second tube 22. The first tube 21 and the second tube 22 are concentrically arranged so as to share a central axis line. The first tube 21 and the second tube 22 each function as a low-pass filter that absorbs infrared light exceeding the above-mentioned peak wavelength. Accordingly, the first tube 21 and the second tube 22 each selectively transmit infrared light having the above-mentioned peak wavelength out of electromagnetic waves radiated from the filament 23.

A space between the first tube 21 and the second tube 22 is defined as a flow path 24. A cooling medium, such as air or an inert gas, can pass through the flow path 24. Thus, heat generated in the filament can be suppressed from being released to the outside of the irradiation unit. In the illustrated example, after having flowed into the flow path 24 through an inflow portion 25 arranged in the second tube 22, the cooling medium passes through the flow path 24 to be discharged from an outflow portion 26 arranged in the second tube 22 (see FIG. 4).

Such wavelength control heater 20 enables smooth performance of the above-mentioned infrared light irradiation step.

In such infrared light irradiation step, the laminate is irradiated with the above-mentioned infrared light, in particular, irradiated with the above-mentioned infrared light until the content of the water in the perovskite semiconductor film becomes equal to or less than the above-mentioned upper limits. Accordingly, even when the photoelectric conversion performance of the prepared laminate is insufficient, the photoelectric conversion performance can be restored. As a result, a photoelectric conversion element having excellent photoelectric conversion performance can be smoothly produced in excellent yield.

### D. Photoelectric Conversion Element

As illustrated in FIG. 2, as in the laminate 1, a photoelectric conversion element 100 produced by the method described in the above-mentioned sections A to C includes the first electrode 11, the electron-transporting layer 13, the perovskite semiconductor film 15, the hole-transporting layer 14, and the second electrode 12. In addition, the photoelectric conversion element 100 further includes the base material 16 as required. Such photoelectric conversion element 100 is suitably used in a solar cell or an electroluminescence (EL) device.

One embodiment of the present invention encompasses a photoelectric conversion element produced by the above-mentioned production method (in particular, a photoelectric conversion element produced by irradiating the above-mentioned laminate 1 with infrared light until the content of the water in the perovskite semiconductor film 15 becomes 1,000 ppm (mass fraction) or less).

Such photoelectric conversion element is validly identified as a “product” because the following circumstances (“impossible or impractical circumstances”) exist: it is impossible or utterly impractical to directly identify the structure of the element because the element is produced through the action of the applied infrared light on the perovskite semiconductor film, the electron-transporting layer, the hole-transporting layer, and/or an interface therebetween.

### E. Method of Regenerating (Reproducing) Photoelectric Conversion Element

In addition, in the above-mentioned method of producing a photoelectric conversion element, a case in which a new photoelectric conversion element is produced has been described in detail. However, the present invention is not limited thereto. The present invention encompasses, for example, a case in which a photoelectric conversion element (i.e., a laminate) reduced in photoelectric conversion performance as a result of its use is recovered, and the photoelectric conversion element after the use is irradiated with infrared light so that the photoelectric conversion performance of the photoelectric conversion element may be regenerated. Thus, a photoelectric conversion element having excellent photoelectric conversion performance can be smoothly reproduced in excellent yield.

### EXAMPLES

The present invention is specifically described below by way of Examples. However, the present invention is not limited to these Examples.

### Example 1

### <<Preparation of Laminate>>

A glass substrate (base material) having arranged thereon an indium tin oxide film (an ITO film, a first electrode) having a thickness of 150 nm was prepared. Next, the glass substrate having arranged thereon the ITO film (hereinafter referred to as “glass substrate with ITO”) was subjected to ultrasonic cleaning, and was then dried.

After that, a colloidal aqueous solution of SnO₂ (manufactured by Alfa Aesar) was diluted to ½ with distilled water, and was applied in an amount of 320 μL/sheet onto the glass substrate with ITO by spin coating. Specifically, the glass substrate with ITO was rotated at 2,000 rpm for 30 seconds, and then the number of revolutions was reduced to 0 rpm at a slope of 2 seconds. After that, the coating film was annealed at 150° C. for 30 minutes. Thus, an electron-transporting layer having a thickness of 40 nm was formed.

Next, a mixed solvent of N,N-dimethylformamide (DMF) and dimethyl sulfoxide (DMSO) (DMF:DMSO=0.77:0.23 (volume ratio)) was added to a mixture containing Cs, formamidine (FA), methylamine (MA), PbI, and Br at 0.05:0.80:0.15:2.68:0.32 (molar ratio), and the above-mentioned mixture was dissolved in the mixed solvent. Thus, a raw material solution having a Pb concentration of 1.3 mol/L was prepared.

Next, the raw material solution was applied in an amount of 190 μL/sheet onto the electron-transporting layer by spin coating. Specifically, after the glass substrate with ITO had been rotated at 1,000 rpm for 10 seconds, the number of revolutions was increased to 3,000 rpm at a slope of 5 seconds, and the substrate was rotated at the number of revolutions for 20 seconds. Subsequently, the number of revolutions was reduced to 0 rpm at a slope of 1 second.

After that, chlorobenzene (300 μL) was further applied to the coating film of the raw material solution by spin coating. The resultant coating film (precursor film) was annealed at 150° C. for 10 minutes to form a perovskite semiconductor film having a thickness of 500 nm.

In addition, a hole-transporting material (Spiro-OMeTAD; 2,2′,7,7′-tetrakis(N,N-di-p-methoxyphenylamine)-9,9′-spirobifluorene; 72.3 mg), [tris(2-(1H-pyrazol-1-yl)-4-tert-butylpyridine)cobalt(III) tris(bis(trifluoromethylsulfonyl)imide)] (FK209; 13.5 mg), 4-tert-butylpyridine (TBP; 28.8 μL), and lithium bis(trifluoromethylsulfonyl)imide (LiTFSI; 9.1 mg) were added to 1 mL of chlorobenzene, and then the resultant was stirred at 70° C. for 30 minutes to prepare a hole-transporting material solution.

After that, the hole-transporting material solution was filtered with a membrane filter, and the filtrate was applied in an amount of 90 μL/sheet onto the perovskite semiconductor film by spin coating. Specifically, the glass substrate with ITO was rotated at 4,000 rpm for 30 seconds, and then the number of revolutions was reduced to 0 rpm at a slope of 4 seconds. After that, the coating film was annealed at 70° C. for 30 minutes. Thus, a hole-transporting layer having a thickness of 200 nm was formed.

Next, a gold thin film (second electrode) having a thickness of 80 nm was formed on the hole-transporting layer by vacuum deposition.

Thus, a laminate having the structure “glass substrate/ITO film (first electrode)/electron-transporting layer/perovskite semiconductor film/hole-transporting layer/gold thin film (second electrode)” was obtained.

### <<Storage of Laminate>>

Next, the resultant laminate was left at rest under an environment at a relative humidity of 30% RH and room temperature (25° C.) for 1 month. Immediately after that, the content of water in the perovskite semiconductor film was measured with a Karl Fischer moisture meter (manufactured by Mitsubishi Chemical Analytech Co., Ltd., trace-moisture measuring apparatus). As a result, the content of the water in the perovskite semiconductor film was more than 1,000 ppm (mass fraction) (more specifically, the content of the water was 3,000 ppm).

When a voltage of 8 V was applied between the ITO film (first electrode) and gold thin film (second electrode) of the laminate, light emission (i.e., photoelectric conversion) was not able to be observed in part of the perovskite semiconductor film.

### <<Irradiation of Laminate With Infrared Light>>

Next, the laminate after its storage was irradiated with infrared light through use of the wavelength control heater illustrated in FIG. 1 for 10 minutes. The environment under which the infrared light was applied had a relative humidity of 30% RH and a temperature of 22° C. In addition, a distance between the surface of the glass base material of the laminate and the infrared light-emitting surface of the wavelength control heater was about 15 cm.

In addition, the infrared light to be applied had a wavelength peak of 1.6 μm and a spectral half-width of about 2.0 μm. In addition, the irradiation energy of the infrared light per unit area was about 0.2 W/cm². The temperature of the laminate at the time of the infrared light irradiation was 60° C.

Thus, a photoelectric conversion element was produced. With regard to the photoelectric conversion element after the infrared light irradiation, the content of water in the perovskite semiconductor film was measured with the above-mentioned Karl Fischer moisture meter. As a result, the content of the water over the entirety of the perovskite semiconductor film was 1,000 ppm (mass fraction) or less (more specifically, the content was 300 ppm or less).

When a voltage of 8 V was applied between the ITO film (first electrode) and gold thin film (second electrode) of the solar cell, it was observed that the entirety of the perovskite semiconductor film satisfactorily emitted light, and hence photoelectric conversion occurred over the entirety of the perovskite semiconductor film.

The method of producing a photoelectric conversion element according to the embodiment of the present invention enables the production of a photoelectric conversion element that may be utilized in various industrial products. The photoelectric conversion element may be suitably used particularly in a solar cell or an electroluminescence (EL) element.

What is claimed is:

1. A method of producing a photoelectric conversion element, comprising the steps of:
preparing a laminate including a first electrode, an electron-transporting layer, a perovskite semiconductor film, a hole-transporting layer, and a second electrode; and
irradiating the laminate with infrared light.

2. The method of producing a photoelectric conversion element according to claim 1, wherein the infrared light has a wavelength peak of 3.5 μm or less.

3. The method of producing a photoelectric conversion element according to claim 2, wherein the infrared light has a spectral half-width of 3.0 μm or less.

4. The method of producing a photoelectric conversion element according to claim 1, wherein in the step of irradiating the laminate with the infrared light, the laminate is irradiated with the infrared light until a content of water in the perovskite semiconductor film becomes 1,000 ppm (mass fraction) or less.

5. The method of producing a photoelectric conversion element according to claim 1, wherein in the step of irradiating the laminate with the infrared light, the laminate has a temperature of 100° C. or less.

6. A photoelectric conversion element, which is produced by irradiating a laminate including a first electrode, an electron-transporting layer, a perovskite semiconductor film, a hole-transporting layer, and a second electrode with infrared light until a content of water in the perovskite semiconductor film becomes 1,000 ppm (mass fraction) or less.
